(19) United States
(12) Patent Application Publication
(10) Pub. No.: US 2001/0012675 A1
(43) Pub. Date: Aug. 9, 2001

(54) SHALLOW TRENCH ISOLATION PROCESS

(76) Inventor: SHYE-LIN WU, HISINCHU (TW)

Correspondence Address: THOMAS T. MOGA, POWELL, GOLDSTEIN, FRAZER & MURPHY, LLP, 1001 PENNSYLVANIA AVE, N.W., SUITE 600, WASHINGTON, DC, 20004, US

(21) Appl. No.: 09/326,858

(22) Filed: Jun. 7, 1999

Related U.S. Application Data
(63) Continuation-in-part of application No. 09/063,210, filed on Apr. 20, 1998, now Pat. No. 5,989,977.

(51) Int. Cl. H01L 21/76

(52) U.S. Cl. 438/435

(57) ABSTRACT

The present invention proposes a method for fabricating shallow trench regions for isolation. A masking oxide layer is patterning on a semiconductor substrate, and the active areas are defined by recessing the semiconductor substrate to form trench regions. Silicon spacers are then formed on the sidewalls of the trench regions by LPCVD of amorphous silicon followed by an anisotropic etching. Sub-trench regions are thus constructed with the silicon spacers as its sidewalls. An ion implantation is performed to form channel stop regions. A thermal oxidation is carried out to grow a thermal oxide layer on the sidewalls and bottoms of the trench regions. A thick CVD oxide layer is deposited on the semiconductor substrate, and the oxide film outside the trench regions is removed by using a CMP process.

### CROSS REFERENCE TO RELATED APPLICATIONS

This invention is a continuation-in-part application filed with a Ser. No. 09/063,210 titled “SHALLOW TRENCH ISOLATION PROCESS”, and assigned to same assignee with the same inventor as the present application.

### FIELD OF THE INVENTION

The present invention relates to a semiconductor device, and more especially, to a method for fabricating shallow trench isolation.

### BACKGROUND OF THE INVENTION

In the integrated circuit industry today, we usually build hundreds of thousands of semiconductor devices on a single chip. Every device on the chip must be electrically isolated to ensure that they operate independently without interfering with each other. The art of isolating semiconductor devices then becomes one important aspect of modern metal-oxide-semiconductor (MOS) and bipolar integrated circuit technology for the separation of different devices or different functional regions. With the high integration of the semiconductor devices, improper isolation among devices will cause current leakage, and the current leakage can consume a significant amount of power. Improper isolation also can exacerbate latch-up, which can damage the circuit temporarily or permanently. In addition, improper isolation can result in noise margin degradation, voltage shift and crosstalk.

Local oxidation of silicon (LOCOS) is one of the most well known techniques for isolation. LOCOS provides the isolation by oxidizing the silicon substrate to create silicon dioxide regions among active devices or functional regions. Because it is easy for the silicon substrate to be oxidized into silicon dioxide, LOCOS has the benefits of its process simplicity and low cost, and it becomes the most widely used isolation technique in very large scale integrated (VLSI) circuit. However, with the tendency for the manufacture of semiconductor integral circuit to high package density, LOCOS meets the limitation in its scalability.

The trench isolation, or, named the shallow trench isolation (STI), is another isolation technique developed especially for semiconductor chip with high integration. The trench regions are formed in the semiconductor substrate by recessing the substrate deep enough for isolation and refilling with insulating material to provide the isolation among active devices or different well regions. In general, trench isolation has a better scalability in comparison with LOCOS isolation.

In the paper “Characteristics of CMOS Device Isolation for the ULSI Age” in IEDM Tech. Dig., p. 671, 1994, by A. Bryant, et al., the two different isolation techniques of LOCOS and STI are investigated. The writers review how LOCOS and STI isolations are being improved to meet the scaling requirements for abrupt active-isolation transitions, isolation depth, and isolation planarity. For deep sub-micron CMOS generation, the conventional LOCOS isolation suffers from several drawbacks such as large lateral extend of bird's beak, non-planarity, local field oxide thinning effect, and stress-induced silicon defects. The key challenges to LOCOS scaling are insulator thinning at narrow dimension, bird's beak formation, and field-implant encroachment. For future CMOS technology, an effective device isolation method that provides abrupt transitions to active device regions with minimum impact on device characteristics or topography will be required. They come to the conclusions that, at the cost of a trench-fill and planarization, STI is a more direct method of meeting these requirements while benefiting from a significant advantage in planarity.

Another support to STI is given by A. H. Perera, et al., in “TRENCH ISOLATION for 0.45 μm ACTIVE PITCH and BELOW” in IEDM Tech. Dig., p. 679, 1995. They state that developing trench isolation appears expedient for technologies at and below the 0.25 μm size scale, due to the predictable scalability of the technique. And, while trench technology is more complex than simple LOCOS isolation, it is of comparable complexity to advanced LOCOS techniques.

Trench isolation develops to be a better isolation technique in deep sub-micron CMOS generation due to the advantages in its scalability, planarity, and isolation depth. But it still encounters several problems such as silicon damage induced by etching and the corner effects. As mentioned by J. A. Mandelman, et al., in the U.S. Pat. No. 5,521,422 entitled “CORNER PROTECTED SHALLOW TRENCH ISOLATION DEVICE”, the parasitic leakage path results from an enhancement of the gate electric field near the trench corner. Even worse, the gate conductor could wrap around the trench corner. They propose for above situation a trench isolation structure with a sidewall around. With this sidewall trench structure, the corner parasitic leakage and the gate wrap-around could be solved.

### SUMMARY OF THE INVENTION

A method for fabricating shallow trench regions on a semiconductor substrate is disclosed. An oxide hard mask is utilized for the silicon etching to form the trenches. A thick thermal oxide film is created at and near the trench corners to prevent the corner effect such as the gate wrap-around and corner parasitic leakage.

Forming and patterning a thick masking oxide layer on a semiconductor substrate, the active areas and isolation regions are defined by recessing the semiconductor substrate to form trench regions. A LPCVD amorphous silicon film is then deposited on entire surface of the semiconductor substrate, and an anisotropic etching is carried out to etch the amorphous silicon film and portions of the substrate on the bottoms of the trench regions. Silicon spacers are then formed on the sidewalls of the trench regions, and sub-trench regions are constructed with the silicon spacers as its sidewalls. An ion implantation is performed to form channel stop regions beneath the sub-trench regions. A thermal oxidation is carried out to grow a thermal oxide layer on the sidewalls and bottoms of the trench regions. A thick CVD oxide layer, which is formed of TEOS-oxide or BPSG, etc., is deposited on the semiconductor substrate. The oxide film outside the trench regions is removed by using a CMP process, and the present invention thus completes.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional view of a semiconductor wafer illustrating the step of forming a patterned masking oxide layer on the substrate and recessing the silicon substrate to form shallow trenches according to the present invention;

FIG. 2 is a cross-sectional view of a semiconductor wafer illustrating the step of depositing an amorphous silicon layer on the substrate according to the present invention;

FIG. 3 is a cross-sectional view of a semiconductor wafer illustrating the step of anisotropically etching the amorphous silicon layer to form silicon spacers on the sidewalls of the trench regions and over etching the bottom of the trench regions of according to the present invention;

FIG. 4 is a cross-sectional view of a semiconductor wafer illustrating the step of performing an ion implantation to form channel stop regions beneath the trench regions according to the present invention;

FIG. 5 is a cross-sectional view of a semiconductor wafer illustrating the step of performing a thermal oxidation to grow a thermal oxide layer on the sidewalls and bottoms of the trench regions according to the present invention;

FIG. 6 is a cross-sectional view of a semiconductor wafer illustrating the step of depositing a CVD oxide layer on the substrate according to the present invention; and

FIG. 7 is a cross-sectional view of a semiconductor wafer illustrating the step of etching back the CVD oxide and the thermal oxide outside the trench regions according to the present invention.

### DESCRIPTION OF THE PREFERRED EMBODIMENT

The present invention proposes a simple method to fabricate shallow trenches for isolation. The method described here includes many process steps well known in the art like photolithography, etching or chemical vapor deposition (CVD) which are not discussed in detail. In addition, the present invention utilizes an oxide hard mask instead of resist mask for the silicon etching to form the trenches. And, a thick thermal oxide film is created to prevent the corner effect such as the gate wrap-around and corner parasitic leakage.

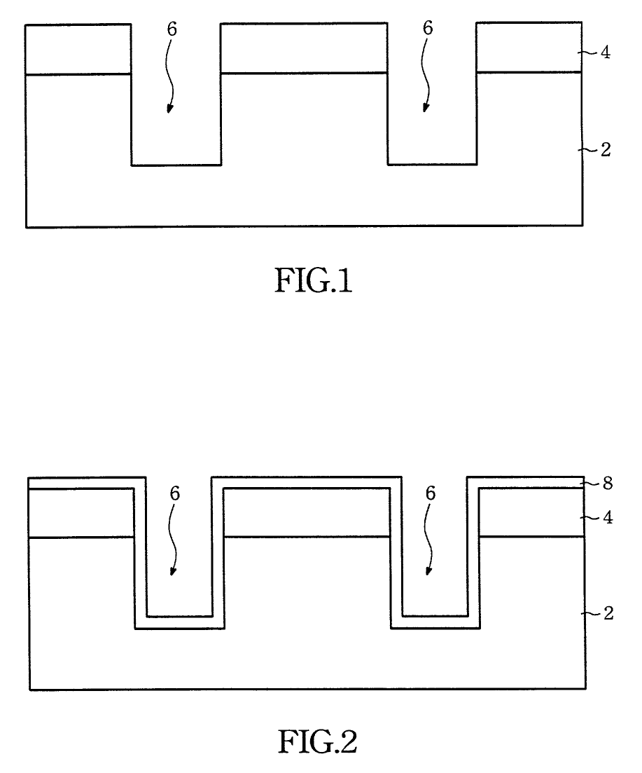

Referring to FIG. 1, a single crystal silicon substrate 2 with a <100> crystallographic orientation is provided. A thick silicon oxide layer 4 is formed on the surface of the substrate 2 to serve as an etching mask later. This silicon oxide layer 4 has a thickness of about 300-2000 angstroms, and can be grown from the semiconductor substrate 2 by using thermal oxidation in a dry or wet oxygen containing ambient at a temperature of about 800-1100° C. Alternatively, this silicon oxide layer 4 can be deposited by using low pressure chemical vapor deposition (LPCVD) at a temperature of about 400-750° C.

Next, a photoresist is now formed on the silicon oxide layer 4 with a trench pattern defined by using a conventional manner of photolithography including photoresist coating, exposure, and development processes. A dry etching process is then performed to etch the thick silicon oxide layer 4 and expose the trench regions of the semiconductor substrate 2. A reactive ion etching (RIE) with plasma gases containing fluoride such as CF₄, CHF₃, C₂F₆ or C₃F₈ is preferable for this anisotropic etching.

After the photoresist is removed and wet cleaned, another dry etching using Cl₂, BCl₃, HBr, SF₆ or SiCl₄ as the plasma source is carried out. At this anisotropic etching step, the exposed portion of the semiconductor substrate 2 is recessed to form the trench regions 6 with a depth deep enough for isolation. As suggested by O. Joubert and F. H. Bell in their paper “Polysilicon Gate Etching in High-Density Plasma: Comparison Between Oxide Hard Mask and Resist Mask” in J. Electrochem. Soc., Vol. 144, p. 1854 at 1997, the patterned thick pad oxide layer 4 is used here as an etching hard mask instead of a resist mask. By the use of the oxide mask, the carbon contamination can be reduced, and the silicon etching process can be developed without creating structure defects.

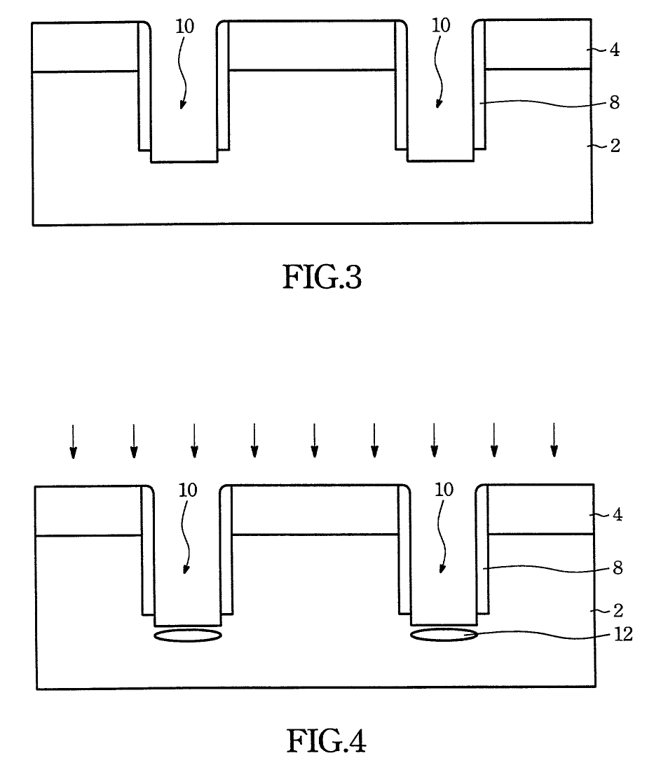

Turning next to FIG. 2, a blanket deposition is carried out, and an amorphous silicon (α-Si) film 8 with a thickness of about 100-500 angstroms is deposited conformally on the entire surface of the semiconductor substrate 2, including the sidewalls and the bottoms of the trench regions 6. A low pressure chemical vapor deposition at a temperature of about 400-560° C. can be applied for this amorphous silicon deposition. Thereafter, a dry etching is carried out to etch back the amorphous silicon film 8, and then silicon spacers 8 are formed on the sidewalls of the trenches. Cl₂, BCl₃, HBr, SF₆ or SiCl₄ can be adopted as the plasma gases for this silicon etching. At this anisotropic etching step, the portions of the amorphous silicon film 6 on the bottoms of the trench regions, as well as on the substrate surface out of the trenches, are removed. Furthermore, the portions of the substrate on the bottoms of the trench regions are simultaneously over etched. Therefore, sub-trench regions 10, which are a little deeper but less wider than the trench regions 6, are formed as shown in FIG. 3.

Referring to FIG. 4, when the sub-trench regions 10 are formed, an ion implantation is then optionally carried out with the ions of opposite conductive type to that of the channel in the active devices. The arrows in FIG. 4 indicate the implanting direction. This opposite type ion implantation is performed for the channel stop 12 beneath the bottom of the sub-trench regions 10 to achieve a better device isolation.

A thermal oxidation in an oxygen containing ambient at a temperature of about 800-1100° C. is now performed. A thick robust thermal oxide layer 14 is grown on the trench surface. In this oxidation step, the remaining amorphous silicon spacers 8 and a portion of the substrate on the bottom of the sub-trench regions 10 are converted into thermal oxide layer 14. The damages induced on the substrate surface by previous dry etching process are recovered through this thermal process. Moreover, due to the higher oxidation rate for amorphous silicon to the silicon substrate of single crystal, a stair-like topography will be formed at the bottom corners of the trench regions, as shown in FIG. 5.

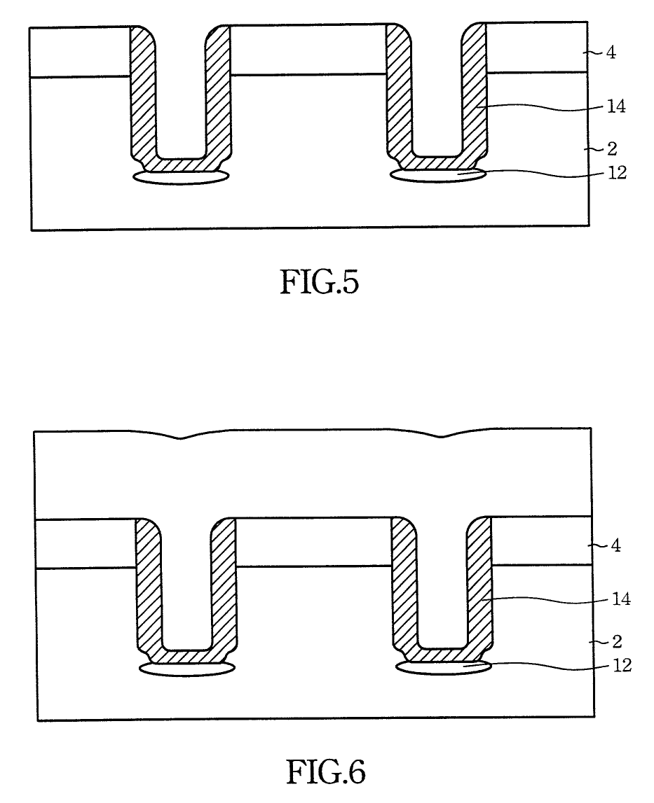

Subsequently, a thick oxide layer 16 is then deposited over the semiconductor substrate 2 and fills the trench region as shown in FIG. 6. The suitable method for forming this thick oxide layer 16 can be LPCVD, PECVD (plasma-enhanced CVD) or HDPCVD (high-density plasma CVD) with the material of tetra-ethyl-ortho-silicate-oxide (TEOS-oxide), ozone TEOS-oxide, boro-phospho silicate glass (BPSG), phospho silicate glass (PSG), boro silicate glass, (BSG), undoped silicate glass (USG) or silicon-rich oxide (SRO), and so on.

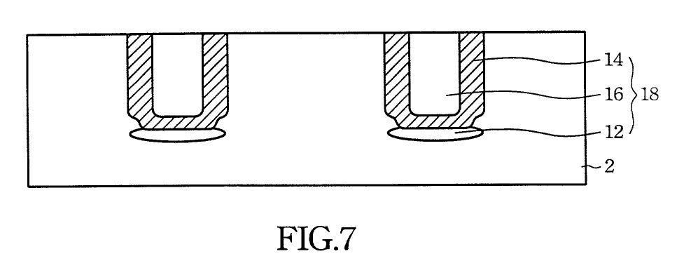

Now referring to FIG. 7, the masking oxide layer 4 and the portion of the thermal oxide layer 14 and the CVD oxide layer 16, which exceeds the trench regions in the semiconductor substrate 2, are stripped. The preferable method for this step can be chemical mechanical polishing (CMP) process for the global planarization that it can provide. Because the thermal oxide 14 is thickly grown over the trenches and the surfaces of the active regions, the same polishing rate is approximately kept at and near the trench corners, and the corner effects such as the gate wraparound and the corner parasitic leakage can be improved. The trenching isolation regions 18, including CVD oxide layers 16, thermal oxide layers 14 and the channel stop regions 12, are thus accomplished with planarized surface.

According to above processes, the trench regions 18 are formed in a semiconductor substrate 2 to provide isolation among active devices. The silicon damages induced by dry etching process would be reduced through high temperature oxidation anneal. The trench regions have rounded top and bottom corners without suffering from corner effects such as the gate wrap-around and the corner parasitic leakage. By solving these problems raised from conventional trench isolation technique, the integration of semiconductor fabrication can be greatly increased, and the method of the present invention can be applied in deep sub-micron or smaller CMOS devices.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for forming trench isolation regions in a semiconductor substrate, said method comprises:
opening trench regions in said semiconductor substrate;
forming silicon spacers on the sidewall of said trench regions in said semiconductor substrate;
performing an oxidation to form a first oxide layer on the sidewalls and bottoms of said trench regions;
forming a second oxide layer on said first oxide layer, thereby filling said trench regions with said second oxide layer; and
removing portions of said first and second oxide layers which exceed said trench regions.

2. The method according to claim 1, further comprising the following steps to form said trench regions:
forming a pad oxide layer on said semiconductor substrate;
patterning said pad oxide layer to expose a portion of said semiconductor substrate which defines said trench regions of said semiconductor substrate; and
etching said semiconductor substrate using said patterned pad oxide layer as an etching mask to form trench regions in said semiconductor substrate.

3. The method according to claim 2, wherein said pad oxide layer has a thickness of about 300 to 2000 angstroms.

4. The method according to claim 2, wherein said trench regions are recessed by an anisotropic etching using a plasma source selected from the group consisting of Cl₂, BCl₃, HBr, SF₆ and SiCl₄.

5. The method according to claim 1, wherein said silicon spacers is formed of amorphous silicon.

6. The method according to claim 1, wherein said silicon spacers is formed by the following steps:
forming a silicon layer on said semiconductor substrate;
etching back said silicon layer by a dry etching process.

7. The method according to claim 6, wherein portions of said semiconductor substrate on said bottoms of said trench regions are over etched by said dry etching process.

8. The method according to claim 1, further comprising an channel stopping implantation step to implant impurity ions into said semiconductor substrate after said silicon spacers are formed.

9. The method according to claim 1, wherein said oxidation is performed in an oxygen containing ambient at a temperature of about 800 to 1100° C.

10. The method according to claim 1, wherein said second oxide layer is formed of a material selected from the group consisting of tetra-ethyl-ortho-silicate-oxide (TEOS-oxide), boro-phospho silicate glass (BPSG), phospho silicate glass (PSG), boro silicate glass, (BSG), and undoped silicate glass (USG).

11. The method according to claim 1, wherein said exceeded portions of said first and second oxide layers are removed by a chemical mechanical polishing (CMP) process.

12. A method for forming trench isolation regions in a semiconductor substrate, said method comprises:
forming a pad oxide layer on said semiconductor substrate;
patterning said pad oxide layer to expose a portion of said semiconductor substrate which defines said trench regions of said semiconductor substrate;
etching said semiconductor substrate using said patterned pad oxide layer as an etching mask to form trench regions in said semiconductor substrate;
forming a silicon layer on said semiconductor substrate;
etching back said silicon layer by a dry etching process, thereby forming silicon spacers on the sidewall of said trench regions in said semiconductor substrate;
performing an oxidation to form a first oxide layer on the sidewalls and bottoms of said trench regions;
forming a second oxide layer on said first oxide layer, thereby filling said trench regions with said second oxide layer; and
removing said patterned pad oxide layer and portions of said first and second thermal oxide layers which exceed said trench regions.

13. The method according to claim 12, wherein said pad oxide layer has a thickness of about 300 to 2000 angstroms.

14. The method according to claim 12, wherein said trench regions are recessed by an anisotropic etching using the plasma source selected from the group consisting of Cl₂, BCl₃, HBr, SF₆ and SiCl₄.

15. The method according to claim 12, wherein said silicon film is formed of amorphous silicon.

16. The method according to claim 12, wherein portions of said semiconductor substrate on said bottoms of said trench regions are over etched by said dry etching process.

17. The method according to claim 12, further comprising an channel stopping implantation step to implant impurity ions into said semiconductor substrate after said silicon spacers are formed.

18. The method according to claim 12, wherein said oxidation is performed in an oxygen containing ambient at a temperature of about 800 to 1100° C.

19. The method according to claim 12, wherein said third oxide layer is formed of a material selected from the group consisting of tetra-ethyl-ortho-silicate-oxide (TEOS-oxide), boro-phospho silicate glass (BPSG), phospho silicate glass (PSG), boro silicate glass, (BSG), and undoped silicate glass (USG).

20. The method according to claim 12, wherein said patterned pad oxide layer and said exceeded portions of said first and second oxide layers are removed by a chemical mechanical polishing (CMP) process.
